(19) United States
(12) Patent Application Publication
(10) Pub. No.: US 2022/0367151 A1
(43) Pub. Date: Nov. 17, 2022

(54) CVD APPARATUS AND FILM FORMING METHOD

(71) Applicant: ASM IP Holding B.V., Almere (NL)

(72) Inventors: Koei Aida, Tokyo (JP); Sam Kim, Chandler, AZ (US)

(21) Appl. No.: 17/739,493

(22) Filed: May 9, 2022

Related U.S. Application Data
(60) Provisional application No. 63/187,547, filed on May 12, 2021.

(51) Int. Cl. H01J 37/32; C23C 16/44; C23C 16/458; C23C 16/455; C23C 16/50

(52) U.S. Cl. CPC H01J 37/32458; H01J 37/32715; C23C 16/4405; C23C 16/4581; C23C 16/45565; C23C 16/50; H01J 2237/3321

(57) ABSTRACT

A CVD apparatus includes a chamber, a susceptor, an entry/takeout port for a substrate, and a gate valve provided at the entry/takeout port, in which the susceptor has a mounting plate and a support, the entry/takeout port is provided on a part of a side of the chamber, and is provided in a range from an inner bottom surface of the chamber to a position corresponding to the lower surface of the mounting plate when the susceptor is located at an upper end in the vertical direction, and the inner bottom surface of the chamber, the range from the inner bottom surface of the chamber to the position corresponding to the lower surface of the mounting plate when the susceptor is located at the upper end in the vertical direction, the lower surface of the mounting plate, and the outer side surface of the support are coated with ceramic liners.

### CROSS-REFERENCE TO RELATED APPLICATIONS

This application claims the benefit of U.S. Provisional Application No. 63/187,547, filed on May 12, 2021, in the United States Patent and Trademark Office, the disclosure of which is incorporated herein in its entirety by reference.

### BACKGROUND OF THE INVENTION

### Field of the Invention

The present disclosure relates to a CVD apparatus and a film forming method.

### Description of Related Art

The chemical vapor deposition (CVD) apparatus is known as a thin film forming apparatus that forms a thin film by depositing a substance generated by a chemical reaction of a source gas containing a thin film component on the surface of a substrate. As the CVD apparatus, a plasma CVD apparatus is widely used. In a plasma CVD apparatus, a chemical reaction is promoted by dissociating a source gas into a plasma state and generating active dissociated molecules, radicals, and ions. In the plasma CVD apparatus, a shower head for introducing the reaction gas into the chamber is arranged at the upper part of the chamber. A susceptor having a mounting plate on which a substrate (e.g., silicon wafer) to be film-formed is mounted is arranged below the shower head, and plasma is generated by applying a radio frequency (RF) voltage between the shower head and the susceptor.

In order to load a substrate into the chamber of the plasma CVD apparatus before the film forming process and to unload the substrate after the film forming process, a chamber is known in which the susceptor can be moved in the vertical direction and an entry/takeout port for the substrate is provided below the side of the chamber (see, US2009/0297731A1). In the chamber having this configuration, during the film forming process, the susceptor is moved to the upper end in the vertical direction to position the substrate near the shower head. Then, after the film forming process, the susceptor is moved to the lower end in the vertical direction to position the substrate near the entry/takeout port for the substrate.

In a chamber having an entry/takeout port for the substrate provided below the side of the chamber, the space below the mounting plate of the susceptor becomes wider during the film forming process. As a result, heat of the susceptor during the film forming process tends to flow out to the space below the susceptor, and the temperature of the substrate to be filmed may become non-uniform. If the temperature of the substrate on which a film is formed becomes non-uniform during film formation, it causes variations in the characteristics and film thickness of the thin film formed on the substrate. Further, when the space below the mounting plate of the susceptor becomes wide, the high frequency voltage applied between the shower head and the susceptor is transmitted to the space below, which causes an abnormal discharge.

### SUMMARY OF THE INVENTION

A first aspect of the present disclosure provides a CVD apparatus including a chamber, a susceptor arranged so as to be movable in the vertical direction inside the chamber, an entry/takeout port for a substrate and a gate valve provided at the entry/takeout port for the substrate, in which the susceptor has a mounting plate having an upper surface on which the substrate is mounted and a support connected to a lower surface of the mounting plate, the entry/takeout port for the substrate is provided on a part of a side of the chamber, and is provided in a range from an inner bottom surface of the chamber to a position corresponding to the lower surface of the mounting plate when the susceptor is located at an upper end in the vertical direction, and the inner bottom surface of the chamber, the part of the side of the chamber in the range from the inner bottom surface of the chamber to the position corresponding to the lower surface of the mounting plate when the susceptor is located at the upper end in the vertical direction, the lower surface of the mounting plate, and the outer side surface of the support are coated with ceramic liners.

In the CVD apparatus according to the aspect, the inner bottom surface of the chamber, the part of the side of the chamber in the range from the inner bottom surface of the chamber to the position corresponding to the lower surface of the mounting plate when the susceptor is located at the upper end in the vertical direction, the lower surface of the mounting plate, and the outer side surface of the support may be coated with ceramic liners through gaps.

In the CVD apparatus according to the aspect, an inert gas supply pipe may be connected to the gaps.

In the CVD apparatus according to the aspect, the inner surface of the entry/takeout port for the substrate may be coated with a ceramic liner.

In the CVD apparatus according to the aspect, the inner surface of the entry/takeout port for the substrate may be coated with a ceramic liner through a gap.

In the CVD apparatus according to the aspect, an inert gas supply pipe may be connected to the gap.

In the CVD apparatus according to the aspect, the mounting plate and the support may contain aluminum nitride, and the ceramic liner covering the lower surface of the mounting plate and the outer side surface of the support may contain Al₂O₃.

The CVD apparatus according to the aspect may include a chamber cleaning gas inlet in which the chamber cleaning gas inlet may be provided on a part of a side of the chamber, and may be provided in a range from an inner bottom surface of the chamber to a position corresponding to the lower surface of the mounting plate when the susceptor is located at an upper end in the vertical direction.

In the CVD apparatus according to the aspect, the chamber cleaning gas may be a gas containing fluorine.

In the CVD apparatus according to the aspect, the chamber may be made of metal.

A second aspect of the present disclosure provides a film forming method including a step of preparing a CVD apparatus comprising a chamber, a susceptor arranged so as to be movable in the vertical direction inside the chamber, an entry/takeout port for a substrate and a gate valve provided at the entry/takeout port for the substrate, wherein the susceptor has a mounting plate having an upper surface on which the substrate is mounted and a support connected to a lower surface of the mounting plate, the entry/takeout port for the substrate is provided on a part of a side of the chamber, and is provided in a range from an inner bottom surface of the chamber to a position corresponding to the lower surface of the mounting plate when the susceptor is located at an upper end in the vertical direction, and the inner bottom surface of the chamber, the part of the side of the chamber in the range from the inner bottom surface of the chamber to the position corresponding to the lower surface of the mounting plate when the susceptor is located at the upper end in the vertical direction, the lower surface of the mounting plate, and the outer side surface of the support are coated with ceramic liners through gaps, and a step of forming a film on the substrate by the CVD method while supplying an inert gas to the gaps.

### BRIEF DESCRIPTION OF THE DRAWINGS

FIG. 1 is a cross-sectional view of an example of the chamber of the CVD apparatus according to one embodiment of the present disclosure.

FIG. 2 is a cross-sectional view of another example of the chamber of the CVD apparatus according to one embodiment of the present disclosure.

FIG. 3 is a cross-sectional view taken along line III-III of FIG. 1.

### DETAILED DESCRIPTION OF THE INVENTION

Hereinafter, the present disclosure will be described in detail with reference to the drawings as appropriate. The drawings used in the following description may be enlarged for convenience in order to make the features of the present invention easy to understand, and the dimensional ratio of each component may differ from the actual one. The materials, dimensions, etc. exemplified in the following description are examples, and the present disclosure is not limited thereto and it is possible to appropriately change and implement the present disclosure within a range in which the effects of the present disclosure can be obtained.

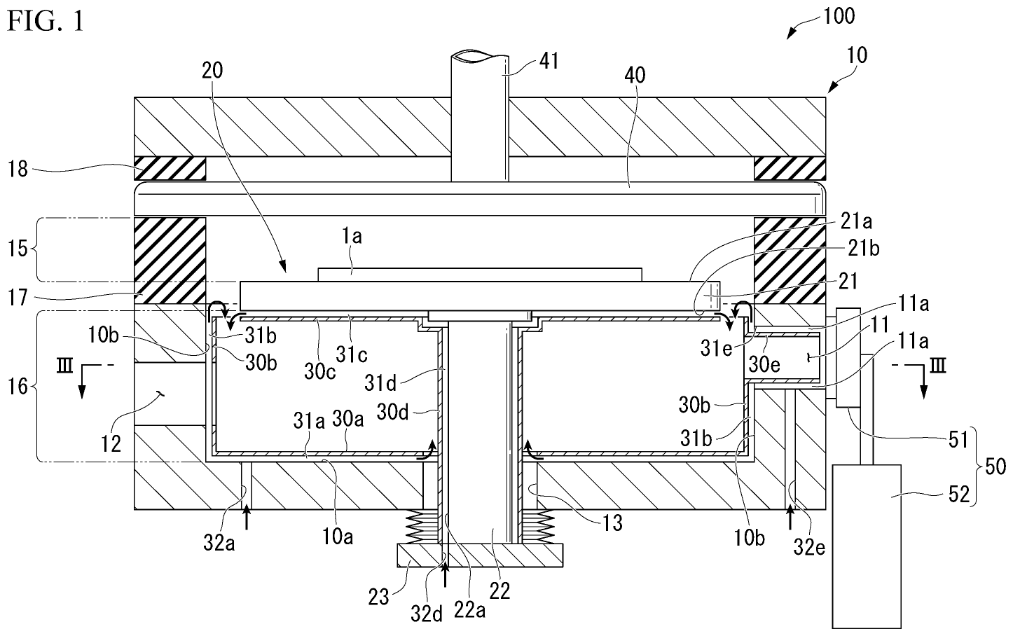

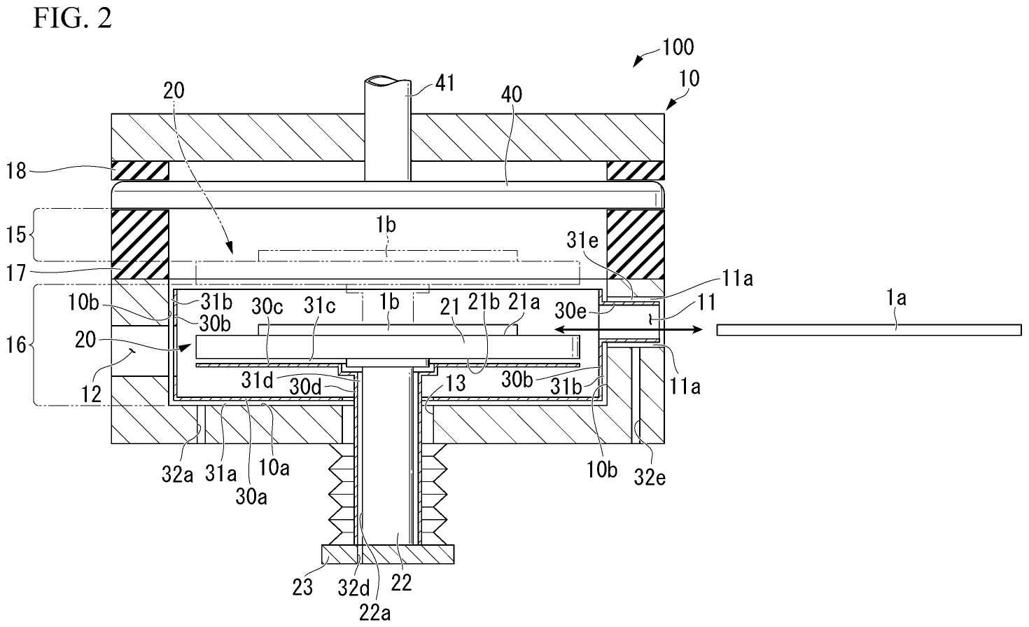

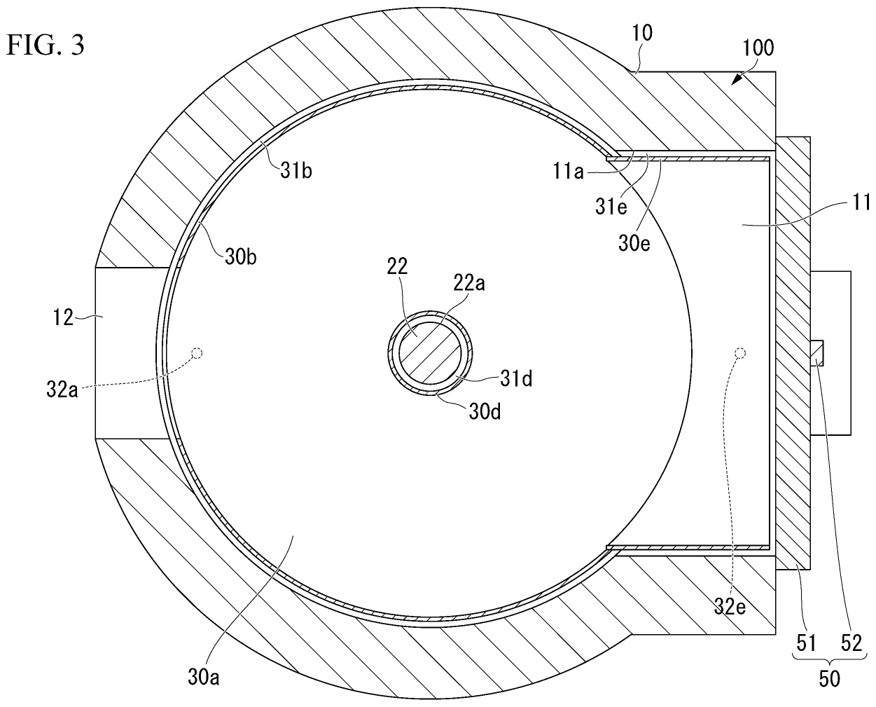

FIG. 1 is a cross-sectional view of an example of a chamber of a CVD apparatus according to an embodiment of the present disclosure. FIG. 1 shows the state in the chamber during the film forming process. FIG. 2 is a cross-sectional view of another example of the chamber of the CVD apparatus according to the embodiment of the present disclosure. FIG. 2 shows the state in the chamber when the substrate is unloaded after the film forming process and the substrate is loaded before the film forming process. FIG. 3 is a cross-sectional view taken along line III-III of FIG. 3.

As shown in FIGS. 1 to 3, the chamber 10 of the CVD apparatus 100 of the present embodiment is a substantially cylindrical body, and an entry/takeout port for the substrate 11 and a chamber cleaning gas inlet 12 are provided on the side of the cylindrical body. Further, a through hole 13 for the susceptor is provided at the bottom of the chamber 10. Further, an exhaust hole (not shown) is provided below or at the bottom of the side of the chamber 10. A shower head 40 is arranged above the inside of the chamber 10. A susceptor 20 is arranged below the shower head 40. The susceptor 20 is movable in the vertical direction. The vertical direction means a direction perpendicular to the inner bottom surface 10a of the chamber 10. The chamber 10 is made of a metal such as stainless steel.

The shower head 40 is connected to the source gas pipe 41. The shower head 40 has a large number of through gas holes (not shown). The source gas supplied from the source gas pipe 41 are discharged downward through the through gas holes of the shower head 40.

The susceptor 20 has a mounting plate 21 and a support 22. The substrate 1a before the film forming process is placed on the upper surface 21a of the mounting plate 21. A support 22 is connected to the lower surface 21b of the mounting plate 21. The support 22 of the susceptor 20 penetrates the through hole for the susceptor 13. The support 22 of the susceptor 20 is fixed to a moving plate 23 supported on the outer bottom surface of the chamber 10. The moving plate 23 is movable in the vertical direction, and the susceptor 20 is configured to move in the vertical direction when the moving plate 23 moves in the vertical direction. In the CVD apparatus of the present embodiment, the upper end of the susceptor 20 in the vertical direction is set to a position where the film forming process can be performed between the shower head 40 and the upper surface 21a of the mounting plate 21 of the susceptor 20. Further, the lower end of the susceptor 20 in the vertical direction is positioned so that the substrate 1b after the film forming process can be unloaded and the substrate 1a before the film forming process can be loaded through the entry/takeout port for the substrate 11. Hereinafter, in the present specification, when the susceptor 20 is located at the upper end in the vertical direction, the region above the upper surface 21a of the mounting plate 21 of the susceptor 20 may be referred to as a reaction region 15, and the region below the lower surface 21b of the mounting plate 21 of the susceptor 20 may be referred to as a susceptor moving region 16.

It is preferable that the mounting plate 21 and the support 22 of the susceptor 20 are formed of a highly thermally conductive material. Aluminum nitride can be mentioned as an example of a highly thermally conductive material. The mounting plate 21 and the support 22 of the susceptor 20 containing aluminum nitride may be operated as a heater by passing an electric current through them.

The entry/takeout port for the substrate 11 is an entry/takeout port for carrying the substrate 1a before the film forming process into the chamber 10 from the outside and carrying out the substrate 1b after the film forming process from the inside of the chamber 10 to the outside (see FIG. 2). The entry/takeout port for the substrate 11 is provided on the side of the chamber 10 in the susceptor moving region 16 (that is, on a part of a side of the chamber 10, and in a range from an inner bottom surface 10a of the chamber 10 to a position corresponding to the lower surface 21b of the mounting plate 21 when the susceptor 20 is located at an upper end in the vertical direction).

A gate valve 50 is provided at the entry/takeout port for the substrate 11. The gate valve 50 has a door member 51 and a drive means 52 connected to the door member 51. The entry/takeout port for the substrate 11 can be opened and closed to the outside by moving the door member 51 by the drive means 52.

The chamber cleaning gas inlet 12 is an inlet port for introducing the chamber cleaning gas into the chamber 10. As the chamber cleaning gas, a gas that is generated during the film forming process and can volatilize by-products deposited inside the chamber 10 can be used. As the chamber cleaning gas, a fluorine-containing compound gas containing fluorine, an oxygen gas, or a mixture of a fluorine-containing compound gas and an oxygen gas can be used. Examples of the fluorine-containing compound gas include NF₃ gas, SF₆ gas, CF₄ gas, and C₂F₆ gas. The chamber cleaning gas may be turned into plasma by using a remote plasma unit (RPU). The chamber cleaning gas inlet 12 is provided on the side of the chamber 10 in the susceptor moving region 16. Further, the chamber cleaning gas inlet 12 may be provided at a position facing the entry/takeout port for the substrate 11.

When cleaning the inside of the chamber 10 with the chamber cleaning gas, the susceptor 20 may be moved to the lower end in the vertical direction. Further, when cleaning the inside of the chamber 10, the inside of the chamber 10 may be heated. The heating temperature of the susceptor 20 may be, for example, in the range of 300° C. or higher and 700° C. or lower. Further, the internal temperature of the chamber 10 may be in the range of 50° C. or higher and 200° C. or lower.

In the CVD apparatus 100 of the present embodiment, the inner surface of the chamber 10 in the susceptor moving region 16 and the surface of the susceptor 20 are coated with ceramic liners. Specifically, the inner bottom surface 10a of the chamber 10 is covered with a ceramic liner 30a. A gap 31a is provided between the inner bottom surface 10a of the chamber 10 and the ceramic liner 30a. In the inner side surface 10b of the chamber 10, a range from the inner bottom surface 10a of the chamber 10 to a position corresponding to the lower surface 21b of the mounting plate 21 when the susceptor 20 is located at the upper end in the vertical direction is covered with a ceramic liner 30b. A gap 31b is provided between the inner side surface 10b of the chamber 10 and the ceramic liner 30b. The lower surface 21b of the mounting plate 21 of the susceptor 20 is covered with a ceramic liner 30c. A gap 31c is provided between the lower surface 21b of the mounting plate 21 and the ceramic liner 30c. The outer side surface 22a of the support 22 of the susceptor 20 is covered with a ceramic liner 30d. A gap 31d is provided between the outer side surface 22a of the support 22 and the ceramic liner 30d. Further, the inner surface 11a of the entry/takeout port for the substrate 11 is covered with a ceramic liner 30e. A gap 31e is provided between the inner surface 1a of the entry/takeout port for the substrate 11 and the ceramic liner 30e.

The ceramic liner 30a, the ceramic liner 30b, and the ceramic liner 30e are connected to each other, whereby the gap 31a, the gap 31b, and the gap 31e are also connected to each other. Further, the gap 31a is connected to the inert gas supply pipe 32a, and the gap 31e is connected to the inert gas supply pipe 32e. The inert gas supply pipe 32a supplies the inert gas to the gap 31a, and the inert gas supply pipe 32e supplies the inert gas to the gap 31e. The inert gas supplied to the gap 31a and the gap 31e is discharged into the chamber 10 through the gap 31b. The discharged inert gas is exhausted to the outside through an exhaust hole (not shown) provided below the bottom or the side of the chamber 10.

The ceramic liner 30c and the ceramic liner 30d are connected to each other, whereby the gap 31c and the gap 31 are also connected to each other. The gap 31d is connected to the inert gas supply pipe 32d. The inert gas supply pipe 32d supplies the inert gas to the gap 31d. The inert gas supplied to the gap 31d is discharged into the chamber 10 through the gap 31c. The discharged inert gas is exhausted to the outside through an exhaust hole (not shown) provided below the bottom or the side of the chamber 10.

The ceramic liners 30a to 30e preferably have lower thermal conductivity than the chamber 10 and the susceptor 20. As the materials of the ceramic liners 30a to 30e, for example, various ceramic materials such as Al₂O₃ can be used. The thickness of the ceramic liners 30a to 30e may be, for example, in the range of 0.5 mm or more and 8 mm or less.

The inert gas supplied to the gaps 31a to 31e is not particularly limited as long as it does not react with the source gas. As the inert gas, for example, nitrogen gas, argon gas, helium gas, and a mixed gas containing two or more of these gases can be used. Each distance of the gaps 31a to 31e may be, for example, within the range of 0.5 mm or more and 15 mm or less. The inert gas supplied to the gaps 31a to 31e passes through the gaps 31a to 31e and is discharged into the inside of the chamber 10 as shown by the arrow in FIG. 1, and is discharged to the outside through an exhaust hole (not shown) provided below the bottom or the side of the chamber 10.

The inner bottom surface 10a of the chamber 10 and the ceramic liner 30a may face each other, and a convex portion may be provided on one surface of those surfaces and a concave portion may be provided on the other surface thereof, and the ceramic liner 30a may be fixed by engaging the convex portion and the concave portion. Similarly, the inner side surface 10b of the chamber 10 and the ceramic liner 30b, the lower surface 21b of the mounting plate 21 and the ceramic liner 30c, the outer side surface 22a of the support 22 and the ceramic liner 30d, or the inner surface 11a of entry/takeout port for the substrate 11 and the ceramic liner 30e may face each other, and a convex portion may be provided on one surface of those surfaces and a concave portion may be provided on the other surface thereof, and these ceramic liners may be fixed by engaging the convex portion and the concave portion. The ceramic liners 30a to 30e may be detachable.

The lower surface of the shower head 40 is supported by the chamber 10 via a first insulating member 17. The upper surface of the shower head 40 is supported by the chamber 10 via a second insulating member 18. As the material of the first insulating member 17 and the second insulating member 18, various ceramic materials such as Al₂O₃ can be used.

Next, a film forming method using the CVD apparatus 100 will be described. The film forming process using the CVD apparatus 100, for example, may include the following steps; a substrate loading step of mounting the substrate 1a on the upper surface of the mounting plate 21 of the susceptor 20, a film forming step of forming a film on the substrate 1a by the CVD method, a substrate unloading step of taking out the substrate 1b after the film forming step.

In the substrate loading step, first, the susceptor 20 is moved to the lower end in the vertical direction. Next, the door member 51 of the gate valve 50 is moved to open the entry/takeout port for the substrate 11 to the outside. Next, after mounting the substrate 1a on the upper surface 21a of the mounting plate 21 of the susceptor 20, the door member 51 of the gate valve 50 is moved to close the entry/takeout port for the substrate 11 to the outside. Then, the susceptor 20 is moved to the upper end in the vertical direction. As a result, the substrate 1a is arranged in the reaction region 15.

In the film forming step, the source gas is discharged toward the substrate 1a from the through gas holes of the shower head 40, and a high frequency (RF) voltage is applied between the shower head 40 and the mounting plate 21 of the susceptor 20 to dissociate the source gas into a plasma state. As a result, active dissociated molecules, radicals, and ions are generated, the chemical reaction is promoted, and a thin film is formed on the surface of the substrate 1a.

In the unloading step, first, the susceptor 20 is moved to the lower end in the vertical direction. Next, the door member 51 of the gate valve 50 is moved to open the entry/takeout port for the substrate 11. As a result, the substrate 1b on which a film is formed 1b can be taken out to the outside.

In the CVD apparatus 100 according to the present embodiment, the susceptor 20 is arranged so as to be movable in the vertical direction. The entry/takeout port for the substrate 11 is provided on a part of a side of the chamber 10, and is provided in a range from the inner bottom surface 10a of the chamber 10 to a position corresponding to the lower surface 21b of the mounting plate 21 when the susceptor 20 is located at the upper end in the vertical direction. Therefore, the susceptor 20 can be moved to the lower end in the vertical direction. According to the CVD apparatus 100 of the present embodiment, the substrate 1a before the film forming process can be smoothly loaded into inside of the chamber 10 from the outside.

In the CVD apparatus 100 according to the present embodiment, the inner surface of chamber 10 of susceptor movement region 16 (that is, the inner bottom surface 10a of the chamber 10, and a part of inner side surface 10b in a range from the inner bottom surface 10a to the position corresponding to the lower surface 21b of the mounting plate 21 when the susceptor 20 is located at the upper end in the vertical direction) is coated with ceramic liners 30a and 30b. As a result, heat of the susceptor moving region 16 (the region below the lower surface 21b of the mounting plate 21) is less likely to be released to the outside during the film forming process. Further, the susceptor 20 in the susceptor moving region 16 (the lower surface 21b of the mounting plate 21 and the outer side surface 22a of the support 22) is covered with ceramic liners 30c and 30d. As a result, heat of the susceptor 20 is less likely to flow out to the susceptor moving region 16 during the film forming process. Since ceramic liners 30a and 30b are interposed between the inner surface of the chamber 10 in the susceptor moving region 16 and the internal space of the chamber 10, the insulation against the high frequency voltage into the space below the mounting plate 21 of the susceptor 20 (susceptor moving region 16) is improved. As a result, abnormal discharge in the lower space is less likely to occur. For the above reasons, the temperature of the susceptor 20 is unlikely to be non-uniform during the film forming process, and the temperature of the substrate 1a is likely to be uniform. Therefore, according to the CVD apparatus 100 of the present embodiment, the characteristics and the film thickness of the thin film formed on the surface of the substrate 1a tend to be uniform.

Further, in the CVD apparatus 100 according to the present embodiment, in the configuration in which the inner surface 11a of the entry/takeout port for the substrate 11 is covered with the ceramic liner 30e, heat of the susceptor moving region 16 is less likely to be released to the outside through the entry/takeout port for the substrate 11 during the film forming process. Therefore, the temperature of the substrate 1a during the film forming process becomes more uniform. As a result, the characteristics and film thickness of the thin film formed on the surface of the substrate 1a tend to be more uniform.

Further, in the CVD apparatus 100 according to the present embodiment, in the configuration in which the inner bottom surface 10b of the chamber 10, the lower surface 21b of the mounting plate 21, the outer side surface 22a of the support 22, and the inner surface 11a of the entry/takeout port for the substrate 11 are covered with ceramic liners through the gap 31, for example, even if the coefficients of thermal expansion differ between those members and the ceramic liners 30a to 30e, stress is less likely to occur between those members and the ceramic liners 30a to 30e. Therefore, the ceramic liners 30a to 30e are less likely to be damaged for a long period of time.

Further, in the CVD apparatus 100 according to the present embodiment, in the configuration in which an inert gas supply pipe is connected to any of the gaps 31a to 31e, by performing the film forming process while supplying the inert gas to the gaps 31a to 31e, it is possible to prevent the by-products generated during the film forming process from accumulating in the gaps 31a to 31e. As a result, the generation of particles is reduced during the film forming process, and by-products are less likely to be mixed into the thin film. Therefore, it is possible to stably form a thin film having more uniform characteristics.

Further, in the CVD apparatus 100 according to the present embodiment, in the configuration in which the chamber cleaning gas inlet 12 is provided on a part of a side of the chamber 10, and is provided in the range from the inner bottom surface 10a of the chamber 10 to the position corresponding to the lower surface 21b of the mounting plate 21 when the susceptor 20 is located at the upper end in the vertical direction, by-products accumulated on the inner surface of the chamber 10 can be removed by introducing the chamber cleaning gas into the chamber 10. As a result, the amount of by-products deposited inside the chamber 10 is reduced, so that the generation of particles can be further reduced. Since the support 22 is covered with the ceramic liner 30d, damage to the support 22 can be suppressed even if the chamber cleaning gas is introduced from the side of the chamber 10.

Further, in the CVD apparatus 100 according to the present embodiment, in the configuration in which the mounting plate 21 and the support 22 contain aluminum nitride, and the ceramic liner 30c covering the lower surface 21b of the mounting plate 21 and the ceramic liner 30d covering the outer side surface of the support 22 contain Al₂O₃, the mounting plate 21 and the support 22 have high thermal conductivity, and the ceramic liners 30c and 30d have low thermal conductivity, making it difficult for heat to be released to the outside. Therefore, the temperature of the susceptor 20 during the film forming process is less likely to be non-uniform, and the temperature of the substrate 1a during the film forming process is likely to be more uniform. Therefore, the characteristics and film thickness of the thin film formed on the surface of the substrate 1a tend to be more uniform.

When the chamber cleaning gas is a fluorine-containing compound gas such as NF₃ gas, by-products accumulated on the inner surface of the chamber 10 can be removed more efficiently. When cleaning the inner surface of the chamber 10 with the fluorine-containing compound gas, the inside of the chamber 10 may be heated to, for example, 50° C. or higher to improve the cleaning efficiency. In the CVD apparatus 100 according to the present embodiment, since the mounting plate 21 and the support 22 of the susceptor 20 are covered with the ceramic liners 30c and 30d, the susceptor 20 is less likely to be damaged even if the inside of the chamber 10 is heated to 50° C. or higher.

In the CVD apparatus 100 according to the present embodiment, in the configuration in which the inner bottom surface 10a of the chamber 10 and the ceramic liner 30a face each other, and a convex portion is provided on one surface of those surfaces and a concave portion is provided on the other surface, and the ceramic liner 30a may be fixed by engaging the convex portion and the concave portion, it becomes easy to make the interval of the gap 31a uniform, and it becomes easy to make the flow rate of the inert gas flowing through the gap 31a constant. The same effect can be obtained also in the configuration in which each of the inner side surface 10b and the ceramic liner 30b of the chamber 10, the lower surface 21b of the mounting plate 21 and the ceramic liner 30c, the outer side surface 22a of the support 22 and the ceramic liner 30d, and the inner surface 11a of entry/takeout port for the substrate 11 and the ceramic liner 30e is fixed by the same fixing means.

In the film forming method according to the present embodiment, since the above-mentioned CVD apparatus 100 is used to form a thin film on the substrate 1a by the CVD method while supplying the inert gas to the gap 31, the temperature of the substrate 1a is uniform, and by-products are less likely to be mixed into the formed thin film. Therefore, according to the film forming method of the present embodiment, a thin film having high characteristics and high uniformity of film thickness can be formed.

The embodiments of the present disclosure have been described so far with reference to the drawings. The present disclosure is not limited to the above-described embodiment, and can be appropriately modified without departing from the technical idea of the present disclosure.

For example, the CVD apparatus 100 of the above-described embodiment is a plasma CVD apparatus having a shower head 40 above the inside of the chamber 10, and the present disclosure is not limited to this configuration. The present disclosure can be applied to, for example, a CVD apparatus in which the support member (susceptor 20) that supports the substrate on which a film is formed is movable in the vertical direction and a film forming step is performed with the support member moved to the upper end in the vertical direction, and a step of unloading the substrate after the film forming process is performed with the support member moved to the lower end in the vertical direction.

Further, in the CVD apparatus 100 of the above-described embodiment of the present embodiment, the inner surface 11a of the entry/takeout port for the substrate 11 of the chamber 10 is covered with the ceramic liner 30e, but the present disclosure is not limited thereto. For example, when the wall thickness of the side of the chamber 10 is thin and heat flowing out from the inner surface 11a of the entry/takeout port for the substrate 11 is small, the ceramic liner 30e may be omitted.

What is claimed is:

1. A CVD apparatus, comprising:
a chamber;
a susceptor arranged so as to be movable in the vertical direction inside the chamber;
an entry/takeout port for a substrate; and
a gate valve provided at the entry/takeout port for the substrate,
wherein the susceptor has a mounting plate having an upper surface on which the substrate is mounted and a support connected to a lower surface of the mounting plate,
the entry/takeout port for the substrate is provided on a part of a side of the chamber, and is provided in a range from an inner bottom surface of the chamber to a position corresponding to the lower surface of the mounting plate when the susceptor is located at an upper end in the vertical direction, and
the inner bottom surface of the chamber, the part of the side of the chamber in the range from the inner bottom surface of the chamber to the position corresponding to the lower surface of the mounting plate when the susceptor is located at the upper end in the vertical direction, the lower surface of the mounting plate, and the outer side surface of the support are coated with ceramic liners.

2. The CVD apparatus according to claim 1,
wherein the inner bottom surface of the chamber, the part of the side of the chamber in the range from the inner bottom surface of the chamber to the position corresponding to the lower surface of the mounting plate when the susceptor is located at the upper end in the vertical direction, the lower surface of the mounting plate, and the outer side surface of the support are coated with ceramic liners through gaps.

3. The CVD apparatus according to claim 2,
wherein an inert gas supply pipe is connected to the gaps.

4. The CVD apparatus according to claim 1,
wherein the inner surface of the entry/takeout port for the substrate is coated with a ceramic liner.

5. The CVD apparatus according to claim 4,
wherein the inner surface of the entry/takeout port for the substrate is coated with a ceramic liner through a gap.

6. The CVD apparatus according to claim 5,
wherein an inert gas supply pipe is connected to the gap.

7. The CVD apparatus according to claim 1,
wherein the mounting plate and the support contain aluminum nitride, and the ceramic liner covering the lower surface of the mounting plate and the outer side surface of the support contains Al₂O₃.

8. The CVD apparatus according to claim 1, further comprising;
a chamber cleaning gas inlet,
wherein the chamber cleaning gas inlet is provided on a part of a side of the chamber, and is provided in a range from an inner bottom surface of the chamber to a position corresponding to the lower surface of the mounting plate when the susceptor is located at an upper end in the vertical direction.

9. The CVD apparatus according to claim 8,
the chamber cleaning gas is a gas containing fluorine.

10. The CVD apparatus according to claim 1,
the chamber is made of metal.

11. A film forming method, comprising:
a step of preparing a CVD apparatus comprising a chamber, a susceptor arranged so as to be movable in the vertical direction inside the chamber, an entry/takeout port for a substrate and a gate valve provided at the entry/takeout port for the substrate, wherein the susceptor has a mounting plate having an upper surface on which the substrate is mounted and a support connected to a lower surface of the mounting plate, the entry/takeout port for the substrate is provided on a part of a side of the chamber, and is provided in a range from an inner bottom surface of the chamber to a position corresponding to the lower surface of the mounting plate when the susceptor is located at an upper end in the vertical direction, and the inner bottom surface of the chamber, the part of the side of the chamber in the range from the inner bottom surface of the chamber to the position corresponding to the lower surface of the mounting plate when the susceptor is located at the upper end in the vertical direction, the lower surface of the mounting plate, and the outer side surface of the support are coated with ceramic liners through gaps, and
a step of forming a film on the substrate by the CVD method while supplying an inert gas to the gaps.
